(19) United States
(12) Patent Application Publication
(10) Pub. No.: US 2007/0178645 A1
(43) Pub. Date: Aug. 2, 2007

(54) Method for manufacturing semiconductor device

(76) Inventor: Osamu Aizawa, Miyagi (JP)

Correspondence Address: VOLENTINE & WHITT PLLC, ONE FREEDOM SQUARE, 11951 FREEDOM DRIVE SUITE 1260, RESTON, VA, 20190, US

(21) Appl. No.: 11/493,009

(22) Filed: Jul. 26, 2006

(30) Foreign Application Priority Data
Jul. 27, 2005 (JP) 217295/2005

(51) Int. Cl. H01L 21/336

(52) U.S. Cl. 438/264

(57) ABSTRACT

The present invention provides a method for manufacturing semiconductor device. An element isolation structural portion is formed in a semiconductor substrate, an element isolation gate insulating film is deposited, a floating gate film is deposited, a spacer film is deposited, and an etching resistant mask pattern is formed on the spacer film. Then, isotropic etching using the etching resistant mask pattern as a mask is performed to remove the spacer film lying in an area broader than an area exposed from the etching resistant mask pattern, which extends from an end edge portion of the etching resistant mask pattern to a lower surface of the etching resistant mask pattern to thereby form a spacer film pattern. Further, anisotropic etching using the etching resistant mask pattern as a mask is performed to remove the floating gate film thereby forming, at an upper end portion, a floating gate having an upper end surface portion placed at an obtuse angle to an exposed end surface.

### BACKGROUND OF THE INVENTION

1. Field of the Invention:

The present invention relates to a method for manufacturing a semiconductor device, and particularly to a method for manufacturing a nonvolatile semiconductor memory device provided with a floating gate.

This application is a counterpart of Japanese patent application, Serial Number 217295/2005, filed on Jul. 27, 2005, the subject matter of which is incorporated herein by reference.

2. Description of the Related Art:

So-called anisotropic etching is generally applied to a floating gage patterning process employed in a method for manufacturing a nonvolatile semiconductor memory device.

A floating gate formed by the anisotropic etching has a tendency that an upper end portion (edge portion) defined by an exposed surface formed by etching and an upper surface of the floating gate assumes an acute angle.

Forming the edge portion in the form of the acute angle in this way yields a thin film portion (Thinning) at a gate oxide film formed so as to cover the edge portion. In particular, the edge portion becomes remarkably thin in the vicinity of an apex angle of the edge portion. Upon the operation of the device, stress is applied onto the thinning of the gate oxide film, so that withstand degradation in each word line occurs between the floating gate and a control gate formed on the floating gate. With such withstand degradation, the escape of charges occurs in the vicinity of the edge portion of the floating gate and hence the electric characteristic of the device is deteriorated.

With a view toward preventing such a charge escape, i.e., an electron trap at the edge portion of the floating gate, a method for manufacturing a nonvolatile semiconductor memory deice has been known wherein isotropic etching is further performed after the formation of a floating gate by anisotropic etching to round off the edge portion (refer to a patent document 1 (Japanese Patent No. 02637149)).

However, according to the manufacturing process of the nonvolatile semiconductor memory device, which has been disclosed in the patent document 1, the isotropic etching in the process of rounding off the edge portion is effected on the entire floating gate. Thus, there is a fear that since the entire floating gate, particularly, the upper surface thereof is etched, the capacitance of the floating gate decreases as compared with a desired or intended capacitance. As a result, there is a fear that an adverse effect is exerted on data write and read characteristics.

Thus, there has been a demand for a technique for providing a nonvolatile semiconductor memory device, which prevents the occurrence of a charge escape in the vicinity of an upper end or edge portion of a floating gate without changing a desired capacitance of the floating gate to thereby avoid degradation in electric characteristic.

### SUMMARY OF THE INVENTION

The present invention has been made in view of the above problems. It is an object of the present invention to provide a method for manufacturing a semiconductor device, which prevents the occurrence of a charge escape in the vicinity of an edge portion of a floating gate without changing a desired capacitance of the floating gate to thereby avoid degradation in electric characteristic.

According to one aspect of the present invention, for attaining the above object, there is provided a method for manufacturing a semiconductor device, comprising the following steps:

A plurality of element forming areas (active regions), an element isolation structural portion forming area which separates the respective adjacent element forming areas (active regions) from each other.

An element isolation structural portion is formed in the element isolation structural portion forming area.

A gate insulating film which covers the upper surface of the substrate and the element isolation structural portion is next grown.

A floating gate film is deposited on the gate oxide film.

A spacer film is deposited on the floating gate film.

An etching resistant mask pattern which covers the floating gafe forming areas, is formed on the spacer film.

Isotropic etching using the etching resistant mask pattern as a mask is effected to remove the spacer film in an area wider than an area exposed from the etching resistant mask pattern, extending from an end edge portion of the etching resistant mask pattern to a side below the etching resistant mask pattern, thereby forming a spacer film pattern having an end edge exposed portion within each of the floating gate forming areas.

Anisotropic etching using the etching resistant mask pattern as a mask is effected to remove the floating gate film thereby to form a floating gate pattern which has an exposed end portion. The exposed end portion includes an obtuse angle with the exposed end surface.

The etching resistant mask pattern and the spacer film pattern are removed.

A second gate insulating film which covers the floating gate and has an inclined surface portion located on the upper end surface portion, is formed.

According to the semiconductor device manufacturing method of the present invention, a spacer film is formed on a floating gate film. Isotropic etching is performed to form a spacer film pattern having an end edge portion within each of floating gate forming areas. Further, anisotropic etching is performed using an etching resistant mask pattern as a mask. It is therefore possible to form a floating gate having an upper end surface portion at an upper end portion or edge portion. As a result, the thickness of a gate insulating film which covers the floating gate, can be made nearly uniform over its entire region. Accordingly, a nonvolatile semiconductor memory device can efficiently be manufactured which prevents the occurrence of a charge escape in the vicinity of an upper end portion of a floating gate without influencing a desired or intended capacitance of the floating gate to thereby avoid degradation in electric characteristic.

### BRIEF DESCRIPTION OF THE DRAWINGS

While the specification concludes with claims particularly pointing out and distinctly claiming the subject matter which is regarded as the invention, it is believed that the invention, the objects and features of the invention and further objects, features and advantages thereof will be better understood from the following description taken in connection with the accompanying drawings in which:

FIGS. 1(A), 1(B) and 1(C) are respectively schematic views showing cut sections of a semiconductor device being in process of its manufacture;

FIGS. 2(A), 2(B) and 2(C) are respectively schematic explanatory views following FIG. 1(C);

FIGS. 3(A), 3(B) and 3(C) are respectively schematic explanatory views following FIG. 2(C); and

FIG. 4 is a schematic explanatory view following FIG. 3(C).

### DETAILED DESCRIPTION OF THE PREFERRED EMBODIMENTS

Preferred embodiments of the present invention will hereinafter be described with reference to the accompanying drawings. Incidentally, the drawings merely schematically show the shape, size and positional relationships of respective components to such a degree that the present invention can be understood. Thus, the present invention is not limited in particular. Incidentally, although specific materials, conditions and numerical conditions or the like might be used in the following description, they are simply preferred examples. Thus, no limitations are imposed on them. It is to be understood that similar components illustrated in the respective drawings used for the following description are respectively identified by the same reference numerals, and the description of certain common components might be omitted.

A preferred embodiment of the present invention will hereinafter be described with reference to the accompanying drawings. Incidentally, the shape, size and physical relationship of each constituent element or component in the figures are merely approximate illustrations to enable an understanding of the present invention. Therefore, the present invention is not limited only to examples illustrated in particular.

Although the specific materials, conditions and numeral conditions or the like might be used in the following description, these are no more than one of preferred examples. Therefore, the present invention is by no means limited by or to these.

Further, be cognizant of the fact that similar constituent elements illustrated in the respective figures used in the following description are given the same reference numerals, and their dual explanations might be omitted.

(Method for Manufacturing Semiconductor Device)

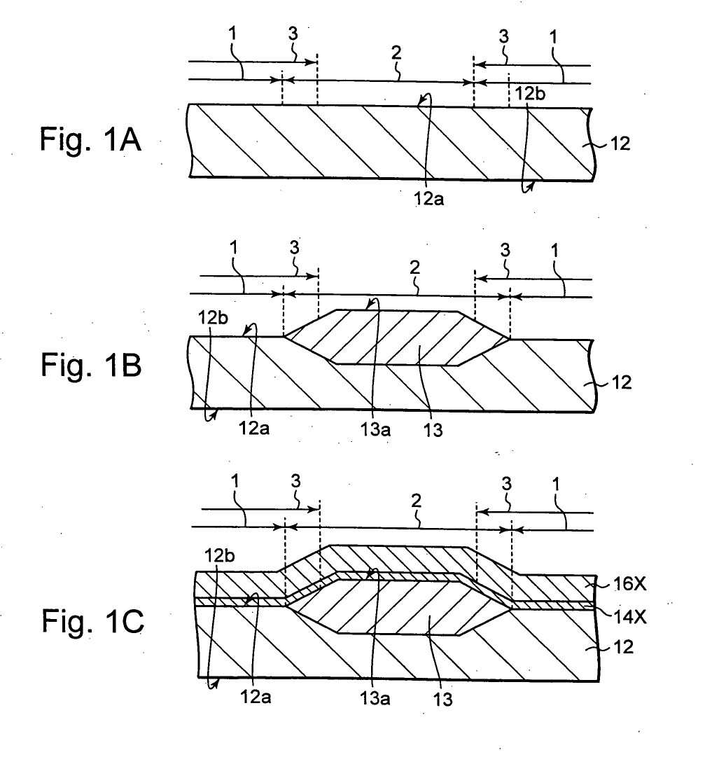

Specific manufacturing processes of a semiconductor device of the present invention will be explained with reference to FIGS. 1, 2, 3 and 4.

FIGS. 1(A), 1(B) and 1(C) are fragmentary schematic views showing cut sections of the semiconductor device being in process of its manufacture.

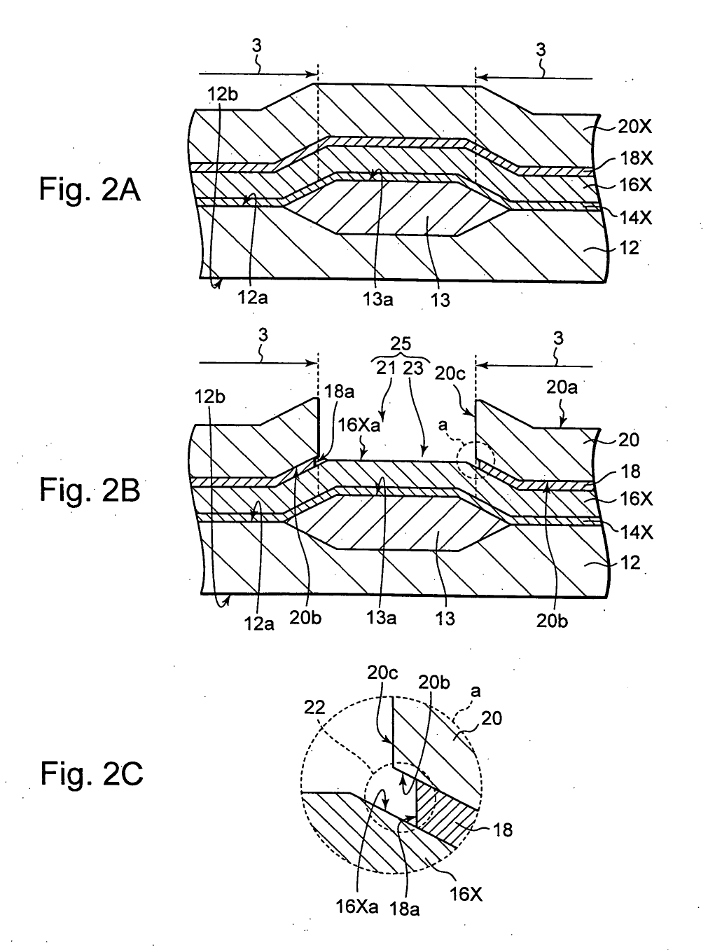

FIGS. 2(A) and 2(B) are views for describing a manufacturing process following FIG. 1(C), and FIG. 2(C) is a partly enlarged view showing an area a of FIG. 2(B) in an enlarged fashion.

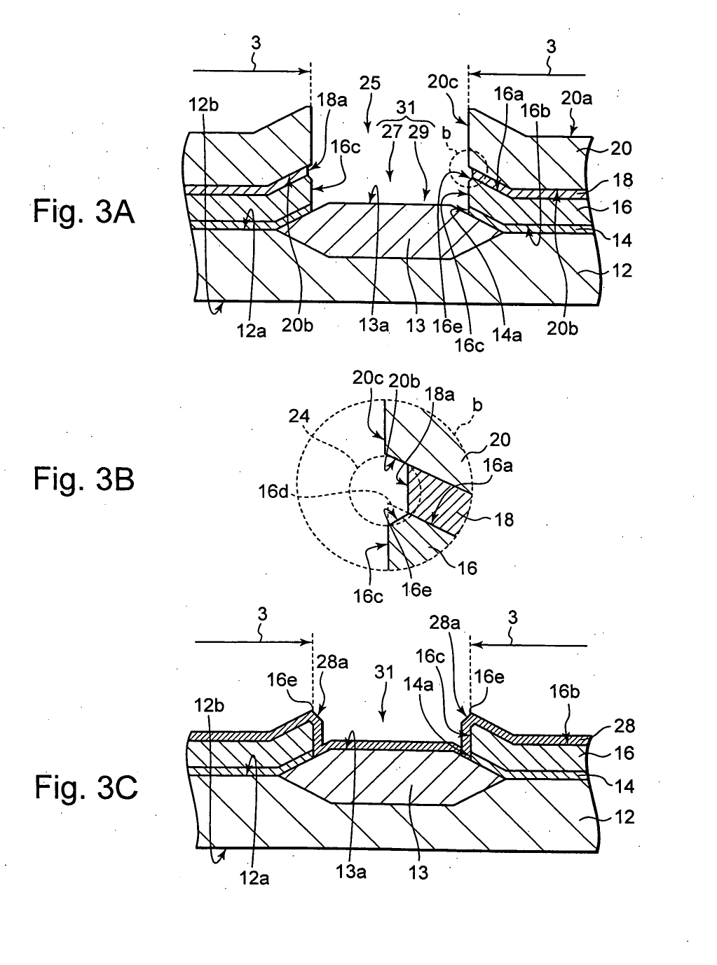

FIGS. 3(A), 3(B) and 3(C) are views for describing a manufacturing process following FIG. 2(C), and FIG. 3(B) is a partly enlarged view showing an area b of FIG. 3(A).

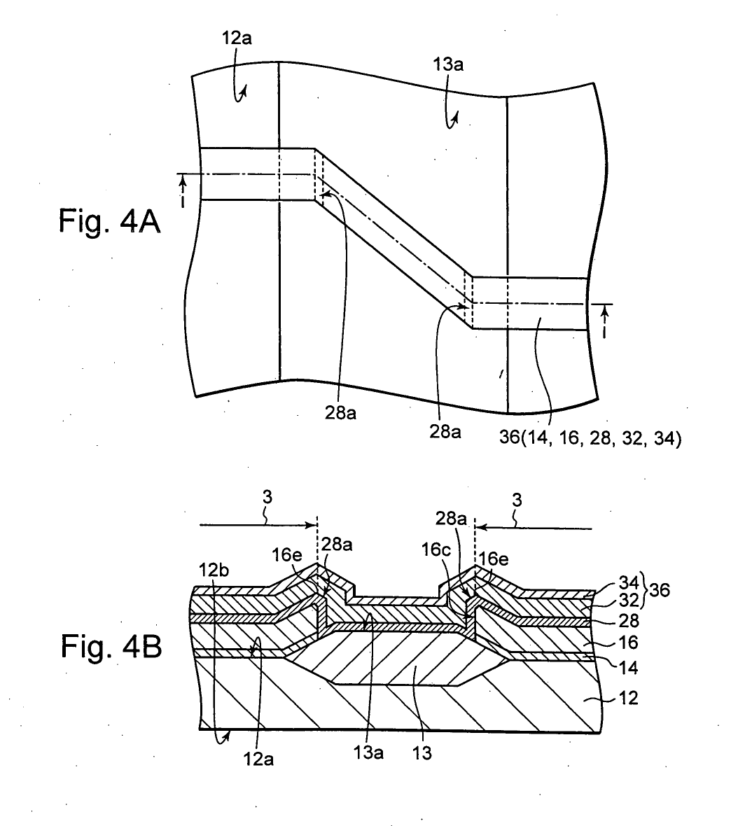

FIGS. 4(A) and 4(B) are explanatory views following FIG. 3(C), wherein FIG. 4(A) is a plan view as seen from above, and FIG. 4(B) is a typical view showing a section cut along dashed line I-I′ of FIG. 4(A).

As shown in FIG. 1(A), a semiconductor substrate 12 is prepared. The semiconductor substrate 12 has an upper surface 12a and a lower surface 12b opposite to the upper surface 12a. A plurality of element forming areas (active regions) 1, an element isolation structure section forming area 2 (field region) which isolates these from each other, and floating gate forming areas 3 are set to the semiconductor substrate 12 in accordance with the design of an intended or target semiconductor device.

Next, an ion implanting process is effected on the element forming areas (active regions) 1 in accordance with a method known per se in the art to form unillustrated ion-implanted regions (well regions), i.e., elements.

Then, as shown in FIG. 1(B), an element isolation structural portion 13 (field insulating film) is formed in the element isolation structural portion forming area 2 (field region) by a method known to date like a LOCOS method.

As shown in FIG. 1(C), an insulative gate oxide film 14X is formed on the upper surface 12a of the semiconductor substrate 12 and the surface 13a of the element isolation structural portion 13 (field insulating film) in accordance with the method known per se in the art. The gate oxide film 14X may preferably be formed in a thickness of 10 nm or so.

Further, a floating gate film 16X doped with, for example, phosphorus (P) is deposited over the entire surface of the gate oxide film 14X. This deposition process may preferably be treated as a process for depositing a polycrystalline silicon film in accordance with an arbitrary and suitable method known to date, e.g., a CVD method and thereafter doping the same with phosphorus or a process for doping it with phosphorus simultaneously with its deposition or growth. The thickness of the floating gate film 16X may preferably be set to 50 nm or so.

Next, as shown in FIG. 2(A), a spacer oxide film 18X is grown or deposited over the entire upper surface of the floating gate film 16X. As the spacer oxide film 18X, a silicon oxide film may be deposited in accordance with the arbitrary and suitable method known to date, e.g., the CVD method. A bottom anti-reflective coating (BARC) known to date can also be applied as the spacer oxide film 18X. The thickness of the spacer oxide film 18X may preferably be set to 40 nm or so.

Further, an etching resistant film 20X is formed over the entire upper surface of the spacer oxide film 18X. The etching resistant film 20X may be formed by, for example, an arbitrary and suitable method using a resist material known to date.

As shown in FIG. 2(B), the etching resistant film 20X is patterned by a photolithography process and an etching process which complies with an arbitrary and suitable method known to date to form an etching resistant mask pattern 20 which covers over each floating gate forming area 3. Etching resistant film portions having remained by patterning of the etching resistant film 20X form the etching resistant mask pattern 20, and an opening or aperture 21 is defined between the remaining adjacent etching resistant films.

Next, a portion of the spacer oxide film 18X, which is exposed from the etching resistant mask pattern 20 is removed with the etching resistant mask pattern 20 as a mask. The process of removing the spacer oxide film 18X is performed by so-called isotropic etching. An opening or aperture 23 communicating with the opening 21 is further defined in the portion of the spacer oxide film 18X exposed to the opening 21 by the isotropic etching, so that both openings are brought to one opening 25.

As the isotropic etching, specifically, plasma etching may preferably be performed under a microwave discharge condition that a mixed gas of a CF₄ gas and an O₂ gas is used at an arbitrary and suitable mixing ratio (flow rate) as an etchant (reaction gas), and the frequency is set to 2.45 GHz (Gigahertz). In consideration of continuity of the next process with the patterning process of the floating gate film 16X, the present isotropic etching process can also be carried out under a so-called RIE (Reactive Ion Etching) discharge condition made assuming that, for example, the pressure is 26.66 Pa (pascals) (equivalent to 200 mTorr) or higher and the frequency is 13.56 MHz (Megahertz).

As shown in FIG. 2(C), the spacer oxide film 18X is removed up to an area lying in the floating gate forming area 3, i.e., an area wider than an area exposed from the etching resistant mask pattern, extending from an end edge portion 20c of the etching resistant mask pattern 20 to the side below the etching resistant mask pattern 20 by the isotropic etching. That is, the opening 23 defined in the spacer oxide film is formed wide such that a predetermined range is exposed along the end edge portion 20c over part of a lower surface 20b of the etching resistant mask pattern 20. As a result, an end edge exposed portion (end surface) 18a of a spacer oxide film pattern 18 is located within the floating gate forming area 3, i.e., outwardly of the end edge portion (end surface) 20c of the etching resistant mask pattern 20 located on the border of the floating gate forming area 3, that is, on the farther inner side lying in the area 3. Thus, the spacer oxide film 18 exposes the surface of the floating gate film 16X in a range wider than a plane size at the time that the etching resistant mask pattern 20 is seen from its upper surface 20a side.

According to this process, a first recess portion 22 defined by the lower surface 20b of the etching resistant mask pattern 20, the end edge exposed portion 18a and the surface 16Xa of the floating gate film 16X is formed as an area for part of the opening 23. The size of the first recess portion 22, i.e., the depth (retreating distance) thereof in the direction orthogonal to the end edge portion 20c of the etching resistant mask pattern 20, i.e., in an outwardly extending direction can be set to one arbitrary and suitable according to a subsequent process and desired design specs of a semiconductor device but may preferably be set so as to be 40 nm or more.

This depth can be set to an arbitrary desired depth by adjusting an etching processing condition, i.e., etching time, pressure and gas partial pressure.

Subsequently, as shown in FIG. 3(A), the floating gate film 16X is patterned by anisotropic etching in accordance with an arbitrary and suitable method known to date using the corresponding etching resistant mask pattern 20 as a mask. An opening or aperture 27 communicating with the above opening 25 is defined in the floating gate film 16X by such patterning. The anisotropic etching can be defined as a conventionally known arbitrary and suitable etching condition corresponding to a material that constitutes the floating gate film 16X. When the floating gate film 16X is of the above polycrystalline silicon film doped with phosphorus, the anisotropic etching may preferably be done under a high-frequency or RF plasma discharge condition that a mixed gas set to an arbitrary and suitable mixing ratio with, for example, HBr and a Cl₂ gas as main reaction gases is used, the pressure is 13.33 pascals (equivalent to 100 mTorr) and the power is 200 watts (W) or so.

Thus, the floating gate film 16X is patterned as a pattern having a size equivalent to the size of the etching resistant mask pattern 20 extending along the end edge portion 20c of the etching resistant mask pattern 20, i.e., as seen from the upper surface 20a side.

The exposed gate oxide film 14X is subsequently patterned (removed) in accordance with a so-called pre-oxidation cleaning process done under an arbitrary and suitable condition known to date in the art, e.g., a wet process using hydrofluoric acid (HF) to come to a gate oxide film pattern 14. With such patterning, an opening or aperture 29 that communicates with the opening 27 is defined in the gate oxide film 14X.

That is, the gate oxide film 14X and the floating gate film 16X are patterned as the gate oxide film pattern 14 and the floating gate 16 such that an exposed surface 14a and an exposed end surface 16c extending in the direction orthogonal to the upper surface 12a of the semiconductor substrate 12 are formed.

As a result, the gate oxide film pattern 14 and the floating gate 16 have shapes identical in contour as seen from the upper sides thereof The gate oxide film pattern 14 and the floating gate 16 are patterned in such a manner that the two exposed end surfaces 16c are opposite to each other on the element isolation structural portion 13 (field insulating film) and so as to have a strip-like form extending in the floating gate forming areas 3 (see FIG. 4(A)). A plane shape of this strip-like form may be bent as illustrated in the figure or may be made linear.

As shown in FIG. 3(B), an upper end portion 16d defined by the exposed end surface 16c of the floating gate 16 and its surface 16a and protruded at an acute angle is chipped away by anisotropic etching for patterning the floating gate film 16X, so that an upper end surface portion 16e is newly formed. Although the upper end surface portion 16e is shown in a flat (linear) fashion in the illustrated example, the upper end surface portion 16e is not limited to it. The upper end surface portion 16e might be shaped in the form of a curved surface. Each upper end surface portion 16e may preferably be placed at an obtuse angle to the exposed end surface 16c and formed so as to connect the surface 16a and the exposed end surface 16c.

The upper end surface portion 16e is formed by allowing the upper end portion 16d to make contact with plasma at an etching process. Thus, the upper end surfaces 16e can be simultaneously formed by the anisotropic etching process for patterning the floating gate 16.

A second recess portion 24 defined by the lower surface 20b of the etching resistant mask pattern 20, the end edge exposed portion 18a and the upper end surface portion 16e of the floating gate 16 is formed according to the present process.

In order to make larger the area of each upper end surface portion 16e formed by the anisotropic etching, a second isotropic etching process may be performed continuously. The second isotropic etching process can be carried out under a conventionally known arbitrary and suitable condition using a mixed gas with, for example, CF₄, O₂ and He as reaction gases.

Since the area of each upper end surface portion 16e can be made wider if done in this way, it is possible to more effectively prevent the occurrence of a thin-film portion of the gate oxide film and prevent degradation of the electric characteristic of the semiconductor device.

Next, the etching resistant mask patterns 20 and the remaining spacer oxide films 18 are removed under an arbitrary and suitable condition known to date in the art. Consequently, the openings 27 and 29 remain as one opening 31.

Next, as shown in FIG. 3(C), a second gate oxide film 28 is formed on the entire exposed surfaces, i.e., inner wall surfaces (containing the surface 13a, exposed surfaces 14a, exposed end surfaces 16c and upper end surface portions 16e) of the opening 31 and the whole area of the surface 16a of the floating gate 16. The second gate oxide film 28 has inclined surface portions 28a defined along the upper end surface portions 16e of the floating gate 16. As a result, the thickness of the second gate oxide film 28 can be set to a substantially uniform thickness over its whole region.

The thickness of the second gate oxide film 28 may be formed as 8 nm or so. The second gate oxide film 28 can be formed by a thermal oxide film forming method which complies with a method known per se in the art.

Further, as shown in FIGS. 4(A) and 4(B), a control gate 36 is formed on the second gate oxide film 28 in accordance with an arbitrary and suitable method known to date. The control gate 36 can be set to such a configuration as known to date in the art.

In the present example, the control gate 36 comprises two layers of a first control gate film 32 provided on the second gate oxide film 28 and a second control gate film 34 provided on the first control gate film 32. These films are sequentially formed over the entire exposed surfaces.

The first control gate film 32 can be formed in a manner similar to the already-described floating gate film 16X. That is, the first control gate film 32 may preferably be formed as a polycrystalline silicon film doped with phosphorus.

The second control gate film 34 may preferably be formed as a tungsten silicide film formed by an arbitrary and suitable deposition or growth method known to date.

These first and second control gate films 32 and 34 are patterned by an arbitrary and suitable patterning process known to date, and the exposed second gate oxide film 28 and floating gate 16 are removed to thereby form the control gate 36, i.e., a so-called cell gate structure.

Although the manufacturing method of the present invention is suitable if applied to, for example, P2ROM (registered trademark), the present invention is not limited to it.

While the present invention has been described with reference to the illustrative embodiments, this description is not intended to be construed in a limiting sense. Various modifications of the illustrative embodiments, as well as other embodiments of the invention, will be apparent to those skilled in the art on reference to this description. It is therefore contemplated that the appended claims will cover any such modifications or embodiments as fall within the true scope of the invention.

What is claimed is:

1. A method for manufacturing a semiconductor device, comprising:
defining a plurality of element forming areas, an element isolation structural portion forming area which separates the respective adjacent element forming areas from each other;
forming an element isolation structural portion in the element isolation structural portion forming area;
depositing a gate oxide film which covers the upper surface of the substrate and the element isolation structural portion;
depositing a floating gate film over the gate oxide film;
depositing a spacer film over the floating gate film;
forming an etching resistant mask pattern covering the floating gate film over the spacer film;
performing isotropic etching using the etching resistant mask pattern as a mask to remove the spacer film in an area wider than an area exposed from the etching resistant mask pattern, extending from an end edge portion of the etching resistant mask pattern to a side below the etching resistant mask pattern, thereby forming a spacer film pattern having an end edge exposed portion;
performing anisotropic etching using the etching resistant mask pattern as a mask to remove the floating gate film thereby to form a floating gate pattern, the floating gate pattern having an exposed end portion including an obtuse angle with an exposed end surface of the floating gate pattern;
removing the etching resistant mask pattern and the spacer film pattern;
forming a second gate oxide film which covers the floating gate pattern;
depositing a control gate film over the second gate oxide film; and
patterning the control gate film to form a control gate pattern.

2. The method according to claim 1, further including a second isotropic etching for making the area of an upper end surface of the exposed end portion of the floating gate pattern larger, after forming the floating gate pattern and before removing the etching resistant mask pattern.

3. The method according to claim 1, wherein distance between the end edge portion of the etching resistant mask pattern and the exposed end portion of the floating gate pattern is equal to or greater than 40 nm in performing isotropic etching.

4. A method for manufacturing a semiconductor device, comprising:
providing a semiconductor substrate;
defining a plurality of active regions, a field region which separates the respective adjacent active regions on a surface of the semiconductor substrate;
forming a field insulating film in the field regions;
depositing a first gate insulating film which covers the active region;
depositing a floating gate film over the first gate insulating film;
depositing a spacer film over the floating gate film;
forming an etching resistant mask pattern covering the floating gate film over the spacer film;
removing the spacer film in an area wider than an area exposed from the etching resistant mask pattern by using the etching resistant mask pattern as a mask;
removing the floating gate film to form a floating gate pattern by using the etching resistant mask pattern as a mask;
removing the etching resistant mask pattern and the spacer film pattern;
forming a second gate insulating film which covers the floating gate pattern;
depositing a control gate film over the second gate insulating film; and
patterning the control gate film to form a control gate pattern.

5. The method according to claim 1, further including a performing an etching for making the area of an upper end surface of the exposed end portion of the floating gate pattern larger, after forming the floating gate pattern and before removing the etching resistant mask pattern.

6. The method according to claim 1, wherein distance between the end edge portion of the etching resistant mask pattern and the exposed end portion of the floating gate pattern is equal to or greater than 40 nm in performing isotropic etching.
